(19) United States
(12) Patent Application Publication
(10) Pub. No.: US 2026/0150665 A1
(43) Pub. Date: May 28, 2026

(54) SEMICONDUCTOR DEVICE

(71) Applicant: Samsung Electronics Co., Ltd., Suwon-si (KR)

(72) Inventors: Hyun Ho JUNG, Suwon-si (KR); Jong Soon PARK, Suwon-si (KR)

(73) Assignee: Samsung Electronics Co., Ltd., Suwon-si (KR)

(21) Appl. No.: 19/208,077

(22) Filed: May 14, 2025

(30) Foreign Application Priority Data
Nov. 25, 2024 (KR) 10-2024-0169528

(51) Int. Cl. H01L 23/522

(52) U.S. Cl. CPC H10W 20/498

(57) ABSTRACT

A semiconductor device includes a first interlayer insulating layer, a lower wiring pattern inside the first interlayer insulating layer, a buffer insulating layer on an upper surface of each of the lower wiring pattern and the first interlayer insulating layer, a resistance pattern in contact with an upper surface of the buffer insulating layer, a second interlayer insulating layer on the upper surface of the buffer insulating layer, the second interlayer insulating layer in contact with each of an upper surface and a sidewall of the resistance pattern, a first via extending, in a vertical direction, through the second interlayer insulating layer and the resistance pattern and into the buffer insulating layer, a vertical level of a lower surface of the first via being lower than a vertical level of a lower surface of the resistance pattern, and a second via spaced apart from the first via in a horizontal direction, the second via extending, in the vertical direction, through the second interlayer insulating layer and the buffer insulating layer, the second via being connected to the lower wiring pattern.

### CROSS-REFERENCE TO RELATED APPLICATION

This application claims priority from Korean Patent Application No. 10-2024-0169528 filed on Nov. 25, 2024 in the Korean Intellectual Property Office, and all the benefits accruing therefrom under 35 U.S.C. 119, the contents of which in its entirety are herein incorporated by reference.

### BACKGROUND

Due to the development of electronic technology, down-scaling of a semiconductor device is rapidly progressing in recent years, such that high integration and low power of a semiconductor chip are required. In order to cope with the demand for the high integration and low power consumption of the semiconductor chip, a feature size of the semiconductor device is continuously decreasing. As various types of contacts are used for connection between adjacent wirings, a length of the contact may increase. Accordingly, contact resistance may increase.

### SUMMARY

Example embodiments of the inventive concepts provide a semiconductor device in which reliability of a connection relationship between a resistance pattern and a via formed in a back-end-of-line (BEOL) process is improved.

Example embodiments of the inventive concepts are not limited to the technical purposes as mentioned above, and other technical purposes as not mentioned may be clearly understood by those skilled in the art from descriptions as set forth below.

According to some example embodiments of the inventive concepts, a semiconductor device includes a first interlayer insulating layer, a lower wiring pattern inside the first interlayer insulating layer, a buffer insulating layer on an upper surface of each of the lower wiring pattern and the first interlayer insulating layer, a resistance pattern in contact with an upper surface of the buffer insulating layer, a second interlayer insulating layer on the upper surface of the buffer insulating layer, the second interlayer insulating layer in contact with each of an upper surface and a sidewall of the resistance pattern, a first via extending, in a vertical direction, through the second interlayer insulating layer and the resistance pattern and into the buffer insulating layer, a vertical level of a lower surface of the first via being lower than a vertical level of a lower surface of the resistance pattern, and a second via spaced apart from the first via in a horizontal direction, the second via extending, in the vertical direction, through the second interlayer insulating layer and the buffer insulating layer, the second via connected to the lower wiring pattern.

According to some example embodiments of the inventive concepts, a semiconductor device includes a first interlayer insulating layer, a lower wiring pattern inside the first interlayer insulating layer, an etch-stop layer on an upper surface of each of the lower wiring pattern and the first interlayer insulating layer, a buffer insulating layer in contact with an upper surface of the etch-stop layer, a resistance pattern in contact with an upper surface of the buffer insulating layer, a second interlayer insulating layer on the upper surface of the buffer insulating layer, the second interlayer insulating layer in contact with each of an upper surface and a sidewall of the resistance pattern, a first via extending, in a vertical direction, through the second interlayer insulating layer and the resistance pattern and into the buffer insulating layer, a vertical level of a lower surface of the first via being lower than a vertical level of a lower surface of the resistance pattern, and the first via overlapping the etch-stop layer in the vertical direction, and a first upper wiring pattern in the second interlayer insulating layer, the first upper wiring pattern being in contact with an upper surface of the first via, and a width in a horizontal direction of a lower surface of the first upper wiring pattern being greater than a width in the horizontal direction of the upper surface of the first via.

According to some example embodiments of the inventive concepts, a semiconductor device includes a first interlayer insulating layer, a lower wiring pattern inside the first interlayer insulating layer, an etch-stop layer on an upper surface of each of the lower wiring pattern and the first interlayer insulating layer, a buffer insulating layer in contact with an upper surface of the etch-stop layer, a resistance pattern in contact with an upper surface of the buffer insulating layer, a second interlayer insulating layer on the upper surface of the buffer insulating layer, the second interlayer insulating layer in contact with a portion of the upper surface of the buffer insulating layer and each of an upper surface and a sidewall of the resistance pattern, a first via extending, in a vertical direction, through the second interlayer insulating layer and the resistance pattern and into the buffer insulating layer, a vertical level of a lower surface of the first via being lower than a vertical level of a lower surface of the resistance pattern, the first via overlapping the etch-stop layer in the vertical direction, and the lower surface of the first via spaced apart from the upper surface of the etch-stop layer in the vertical direction, a second via spaced apart from the resistance pattern in a horizontal direction, the second via extending through the second interlayer insulating layer, the buffer insulating layer and the etch-stop layer in the vertical direction, the second via being connected to the lower wiring pattern, and a vertical level of a lower surface of the second via being lower than the vertical level of the lower surface of the first via, a first upper wiring pattern in the second interlayer insulating layer, the first upper wiring pattern being in contact with an upper surface of the first via, a width in the horizontal direction of a lower surface of the first upper wiring pattern being greater than a width in the horizontal direction of the upper surface of the first via, and the first via and the first upper wiring pattern being formed integrally with each other, and a second upper wiring pattern in the second interlayer insulating layer, the second upper wiring pattern being in contact with an upper surface of the second via, a width in the horizontal direction of a lower surface of the second upper wiring pattern being greater than a width in the horizontal direction of the upper surface of the second via, the second upper wiring pattern being spaced apart from the first upper wiring pattern in the horizontal direction, and the second via and the second upper wiring pattern being formed integrally with each other.

According to some example embodiments, a method of fabrication a semiconductor device includes forming a first interlayer insulating layer on a substrate, forming a lower wiring pattern inside the first interlayer insulating layer, forming a buffer insulating layer on the lower wiring pattern and the first interlayer insulating layer, forming a resistance pattern on an upper surface of the buffer insulating layer, forming a second interlayer insulating layer on the upper surface of the buffer insulating layer such that the second interlayer insulating layer is in contact with each of an upper surface and a sidewall of the resistance pattern, forming a first via extending through the second interlayer insulating layer and the resistance pattern in a vertical direction and into the buffer insulating layer such that a vertical level of a lower surface of the first via is lower than a vertical level of a lower surface of the resistance pattern, and forming a second via spaced apart from the first via in a horizontal direction such that the second via extends through the second interlayer insulating layer and the buffer insulating layer in the vertical direction and the second via connects to the lower wiring pattern.

According to some example embodiments, the method may further include forming an etch-stop layer on the lower wiring pattern, wherein the forming the buffer insulating layer includes forming the buffer insulating layer on the etch-stop layer, wherein the forming the first via includes forming the first via overlapping the etch-stop layer in the vertical direction, and wherein the forming the second via includes forming the second via extending through the etch-stop layer.

According to some example embodiments, the forming the first via may include forming the first via such that a lower surface of the first via is spaced apart from an upper surface of the etch-stop layer in the vertical direction.

According to some example embodiments, the forming the first via may include forming the first via such that the first via contacts an upper surface of the etch-stop layer.

According to some example embodiments, the forming the second via may include forming the second via spaced apart from the resistance pattern in the horizontal direction.

According to some example embodiments, the forming the second interlayer insulating layer may include forming the second interlayer insulating layer such that at least a portion of the upper surface of the buffer insulating layer is in contact with the second interlayer insulating layer.

According to some example embodiments, the forming the second via may include forming the second via such that a vertical level of a lower surface of the second via is lower than the vertical level of the lower surface of the first via.

According to some example embodiments, the method may include forming a first upper wiring pattern in the second interlayer insulating layer such that the first upper wiring pattern in contact with an upper surface of the first via, and a width in the horizontal direction of a lower surface the first upper wiring pattern is greater than a width in the horizontal direction of the upper surface of the first via, and forming a second upper wiring pattern in the second interlayer insulating layer such that the second upper wiring pattern is in contact with an upper surface of the second via, a width in the horizontal direction of a lower surface of the second upper wiring pattern is greater than a width in the horizontal direction of the upper surface of the second via, and the second upper wiring pattern is spaced apart from the first upper wiring pattern in the horizontal direction.

According to some example embodiments, the forming the first via may include forming the first upper wiring pattern integrally with the first via, and the forming the second via may include forming the second upper wiring pattern integrally with the second via.

The specific details of some example embodiments are included in the detailed description and drawings.

### BRIEF DESCRIPTION OF DRAWINGS

The above and other example embodiments of the inventive concepts will become more apparent by describing some example embodiments thereof with reference to the attached drawings, in which:

FIG. 1 is a layout diagram for illustrating a semiconductor device according to some example embodiments of the inventive concepts;

FIG. 2 is a cross-sectional view taken along a line A-A′ of FIG. 1;

FIG. 3 is an enlarged view of a region R1 of FIG. 2;

FIGS. 4 to 8 are diagrams illustrating intermediate structures corresponding to intermediate steps of a method for fabricating a semiconductor device according to some example embodiments of the inventive concepts;

FIG. 9 is a cross-sectional view illustrating a semiconductor device according to some example embodiments of the inventive concepts;

FIG. 10 is an enlarged view of a region R2 of FIG. 9;

FIG. 11 is a cross-sectional view illustrating a semiconductor device according to some example embodiments of the inventive concepts;

FIG. 12 is a cross-sectional view illustrating a semiconductor device according to some example embodiments of the inventive concepts;

FIG. 13 is an enlarged view of a region R3 of FIG. 12;

FIG. 14 is a cross-sectional view illustrating a semiconductor device according to some example embodiments of the inventive concepts; and

FIG. 15 is an enlarged view of a region R4 of FIG. 14.

### DETAILED DESCRIPTIONS

Hereinafter, some example embodiments of the inventive concepts will be described in detail with reference to the accompanying drawings. The same reference numerals are used for the same components in the drawings, and redundant descriptions thereof will be omitted.

Although terms such as first, second, upper, and lower are used herein to describe various elements or components, it is obvious that these element or components are not limited by the terms. Rather, the terms are merely used herein to distinguish one element or component from another element or component. Therefore, it is obvious that a first element or component as mentioned below may also be a second element or component within the technical spirit of the inventive concepts. Further, it is obvious that a lower element or component as mentioned below may also be an upper element or component within the technical spirit of the inventive concepts.

It will be understood that when an element is referred to as being “connected” or “coupled” to another element, or “contacting” or in “contact with” another element, it can be directly connected or coupled or directly contacting or directly in contact with the other element or intervening elements may be present. In contrast, when an element is referred to as being “directly connected” or “directly coupled” to another element, or “directly contacting” or “in direct contact with” another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

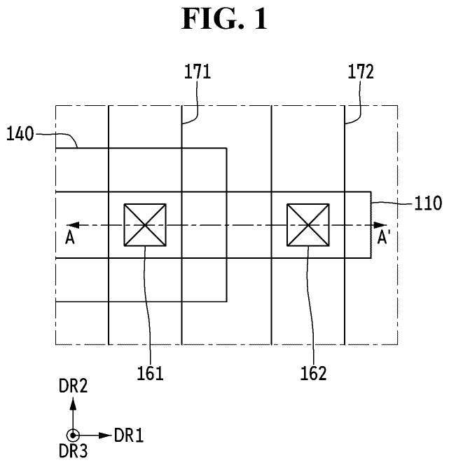

Hereinafter, a semiconductor device according to some example embodiments of the inventive concepts will be described with reference to FIGS. 1 to 3.

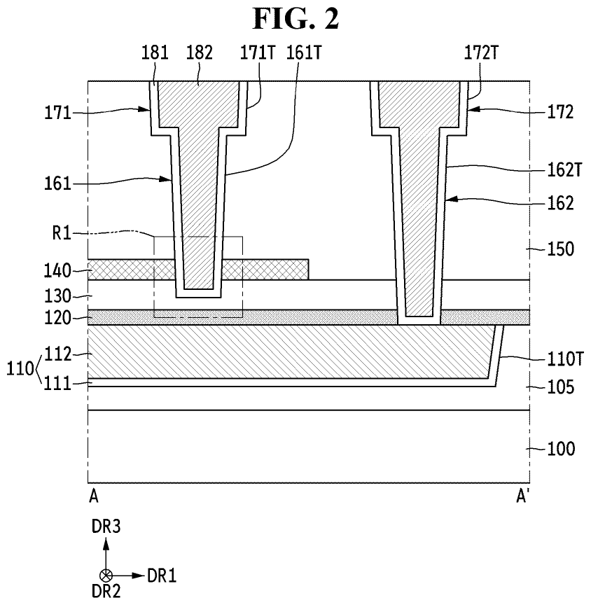

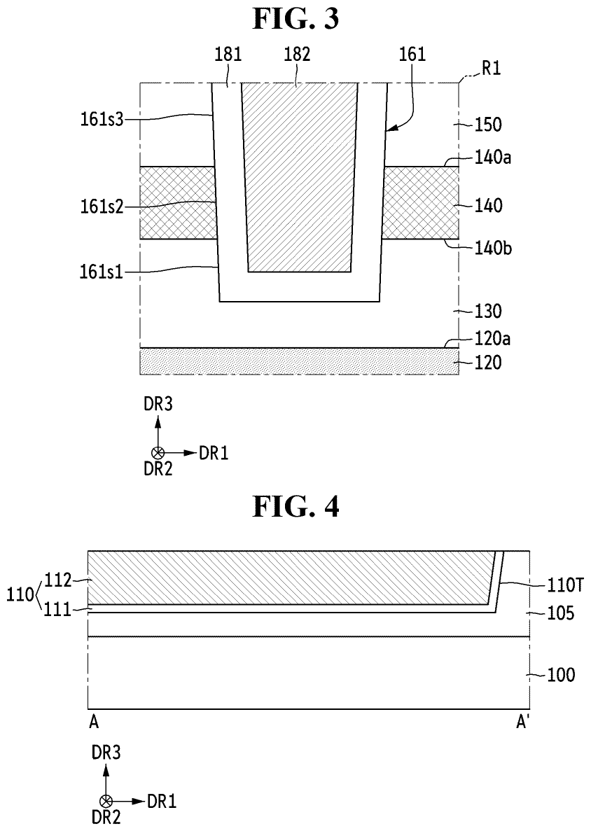

FIG. 1 is a layout diagram for illustrating a semiconductor device according to some example embodiments of the inventive concepts. FIG. 2 is a cross-sectional view taken along a line A-A′ of FIG. 1. FIG. 3 is an enlarged view of a region R1 of FIG. 2.

Referring to FIGS. 1 to 3, the semiconductor device according to some example embodiments of the inventive concepts includes a substrate 100, a first interlayer insulating layer 105, a lower wiring pattern 110, an etch-stop layer 120, a buffer insulating layer 130, a resistance pattern 140, a second interlayer insulating layer 150, a first via 161, a second via 162, a first upper wiring pattern 171, and/or a second upper wiring pattern 172.

The substrate 100 may have a structure in which a base substrate and an epitaxial layer are stacked. However, the example embodiments are not limited thereto.

The substrate 100 may be a silicon substrate, a gallium arsenide substrate, a silicon germanium substrate, a ceramic substrate, a quartz substrate, a glass substrate for display, and/or a semiconductor on insulator (SOI) substrate. In addition, although not shown, the substrate 100 may include a conductive pattern. The conductive pattern may be a metal wire, a contact, and/or the like, and may be a gate electrode of a transistor, a source/drain of a transistor, a diode, and/or the like. However, the example embodiments are not limited thereto.

In some example embodiments, the substrate 100 may include a fin-type transistor (FinFET) including a channel region having a fin-type pattern shape, a transistor including a nanowire and/or a nanosheet, an MBCFET™ (Multi-Bridge Channel Field Effect Transistor) and/or a vertical transistor (Vertical FET). In some example embodiments, the substrate 100 may include a planar transistor, a bipolar junction transistor, and/or a lateral double diffused MOS (LDMOS).

Hereinafter, each of the first horizontal direction DR1 and the second horizontal direction DR2 may be defined as a direction parallel to an upper surface of the substrate 100. The second horizontal direction DR2 may be defined as a direction different from the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the substrate 100.

The first interlayer insulating layer 105 may be disposed on the upper surface of the substrate 100. For example, the first interlayer insulating layer 105 may include one or more of silicon oxide, silicon nitride, silicon oxynitride, and/or a low dielectric constant (low-k) material. For example, the low dielectric constant material may include, for example, tetraethyl orthosilicate (TEOS), fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, and/or combinations thereof. However, the example embodiments are not limited thereto.

A lower wiring trench 110T may be formed inside the first interlayer insulating layer 105. The lower wiring trench 110T may be formed to be recessed from an upper surface of the first interlayer insulating layer 105 toward the inside of the first interlayer insulating layer 105. For example, the lower wiring trench 110T may extend in the first horizontal direction DR1. For example, a sidewall and a bottom surface of the lower wiring trench 110T may be defined by the first interlayer insulating layer 105. For example, a width of the lower wiring trench 110T in the first horizontal direction DR1 may continuously increase as the lower wiring trench 110T extends toward the upper surface of the first interlayer insulating layer 105.

The lower wiring pattern 110 may be disposed inside the lower wiring trench 110T. That is, the lower wiring pattern 110 may be disposed inside the first interlayer insulating layer 105. For example, the lower wiring pattern 110 may extend in the first horizontal direction DR1. For example, a width of the lower wiring pattern 110 in the first horizontal direction DR1 may continuously increase as the lower wiring pattern 110 extends toward the upper surface of the first interlayer insulating layer 105. For example, an upper surface of the lower wiring pattern 110 may not be covered with the upper surface of the first interlayer insulating layer 105 so as to be exposed. The lower wiring pattern 110 may include a first wiring barrier layer 111 and/or a first wiring filling layer 112.

The first wiring barrier layer 111 may be disposed along a sidewall and/or a bottom surface of the lower wiring trench 110T. For example, the first wiring barrier layer 111 may be conformally formed. For example, the uppermost surface of the first wiring barrier layer 111 may not be covered with the upper surface of the first interlayer insulating layer 105 so as to be exposed. For example, the first wiring barrier layer 111 may include at least one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), and/or a combination thereof. However, example embodiments are not limited thereto.

The first wiring filling layer 112 may be disposed on the first wiring barrier layer 111 and inside the lower wiring trench 110T. The first wiring filling layer 112 may fill the inside of the lower wiring trench 110T while being disposed on the first wiring barrier layer 111. For example, the upper surface of the first wiring filling layer 112 may not be covered with the upper surface of the first interlayer insulating layer 105 so as to be exposed. For example, the first wiring filling layer 112 may include one or more of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), and/or rhodium (Rh). However, example embodiments are not limited thereto.

The etch-stop layer 120 may be disposed on an upper surface of the lower wiring pattern 110 and an upper surface of the first interlayer insulating layer 105. The etch-stop layer 120 may be in contact with each, or one or more, of the upper surface of the lower wiring pattern 110 and/or the upper surface of the first interlayer insulating layer 105. For example, the etch-stop layer 120 may be conformally formed. In FIG. 2, the etch-stop layer 120 is illustrated as being formed as a single film. However, the example embodiments are not limited thereto. In some example embodiments, the etch-stop layer 120 may be formed as a stack of multiple films. For example, the etch-stop layer 120 may include one or more of aluminum nitride (AlN), aluminum oxide (AlO), hafnium oxide (HfO), zirconium oxide (ZrO), hafnium nitride (HfN), zirconium nitride (ZrN), silicon oxide (SiO2), silicon nitride (SiN), silicon oxynitride (SiCN), silicon oxycarbide (SiOC), silicon carbide (SiC), and/or a low dielectric constant material.

The buffer insulating layer 130 may be disposed on an upper surface 120a of the etch-stop layer 120. The buffer insulating layer 130 may be in contact with the upper surface 120a of the etch-stop layer 120. For example, the etch-stop layer 120 may be disposed between the buffer insulating layer 130 and the upper surface of each, or one or more, of the lower wiring pattern 110 and/or the first interlayer insulating layer 105. For example, the buffer insulating layer 130 may include silicon oxide, silicon nitride, silicon oxynitride, and/or a low dielectric constant material. For example, the buffer insulating layer 130 may include TEOS (tetraethyl orthosilicate).

The resistance pattern 140 may be disposed on an upper surface of the buffer insulating layer 130. For example, the resistance pattern 140 may be disposed on a portion of the upper surface of the buffer insulating layer 130. For example, the resistance pattern 140 may not be disposed on at least a portion of the upper surface of the buffer insulating layer 130. A bottom surface 140b of the resistance pattern 140 may be in contact with the upper surface of the buffer insulating layer 130. In FIGS. 2 and 3, the resistance pattern 140 is illustrated as being formed as a single film. However, example embodiments are not limited thereto. In some example embodiments, the resistance pattern 140 may be formed as a stack of multiple films.

For example, the resistance pattern 140 may include one or more of a metal, a conductive metal nitride, a conductive metal carbonitride, a conductive metal carbide, a metal silicide, a doped semiconductor material, a conductive metal oxynitride, and/or a conductive metal oxide. For example, the resistance pattern 140 may include a metal nitride. For example, the resistance pattern 140 may include at least one of a tantalum nitride (TaN) film, a titanium nitride (TiN) film, and/or a combination thereof.

The second interlayer insulating layer 150 may be disposed on the upper surface of the buffer insulating layer 130. The second interlayer insulating layer 150 may cover an upper surface 140a and/or a sidewall of the resistance pattern 140 while being disposed on the upper surface of the buffer insulating layer 130. For example, the second interlayer insulating layer 150 may be in contact with each, or one or more, of the upper surface 140a and/or the sidewall SW of the resistance pattern 140. At least a portion of the second interlayer insulating layer 150 may be in contact with the upper surface of the buffer insulating layer 130. For example, the second interlayer insulating layer 150 may be in contact with the upper surface of the buffer insulating layer 130 while being disposed on the sidewall of the resistance pattern 140. For example, the second interlayer insulating layer 150 may include one or more of silicon oxide, silicon nitride, silicon oxynitride, and/or a low dielectric constant material. For example, the second interlayer insulating layer 150 may include a material different from that of the first interlayer insulating layer 105. However, example embodiments are not limited thereto. In some example embodiments, the second interlayer insulating layer 150 may include the same material as that of the first interlayer insulating layer 105.

A first via trench 161T may be formed inside the second interlayer insulating layer 150. The first via trench 161T may extend through the second interlayer insulating layer 150 and/or the resistance pattern 140 in the vertical direction DR3 so as to extend into the buffer insulating layer 130. For example, a bottom surface of the first via trench 161T may be formed inside the buffer insulating layer 130. A vertical level of the bottom surface of the first via trench 161T may be lower than a vertical level of the bottom surface 140b of the resistance pattern 140. For example, the vertical level of the bottom surface of the first via trench 161T may be higher than a vertical level of the upper surface 120a of the etch-stop layer 120.

A second via trench 162T may be formed in the second interlayer insulating layer 150. The second via trench 162T may be spaced apart from the first via trench 161T in the first horizontal direction DR1. For example, the second via trench 162T may be spaced apart from the resistance pattern 140 in the first horizontal direction DR1. The second via trench 162T may extend through the second interlayer insulating layer 150, the buffer insulating layer 130, and/or the etch-stop layer 120 in the vertical direction DR3 so as to extend to the upper surface of the lower wiring pattern 110.

The first via 161 may be disposed inside the first via trench 161T. The first via 161 may extend through the second interlayer insulating layer 150 and/or the resistance pattern 140 in the vertical direction DR3 so as to extend into the buffer insulating layer 130. For example, a lower surface of the first via 161 may contact the buffer insulating layer 130. For example, a vertical level of the lower surface of the first via 161 may be lower than a vertical level of the lower surface 140 b of the resistance pattern 140. For example, the first via 161 may overlap the etch-stop layer 120 in the vertical direction DR3. For example, the lower surface of the first via 161 may be formed between the upper surface 120 a of the etch-stop layer 120 and the lower surface 140 b of the resistance pattern 140. For example, the lower surface of the first via 161 may be spaced apart from the upper surface 120a of the etch-stop layer 120 in the vertical direction DR3.

For example, a vertical level of the upper surface of the first via 161 may be lower than a vertical level of the upper surface of the second interlayer insulating layer 150. For example, both opposing sidewalls in the first horizontal direction DR1 of the first via 161 may contact each, or one or more, of the buffer insulating layer 130, the resistance pattern 140, and/or the second interlayer insulating layer 150. For example, a sidewall in the first horizontal direction DR1 of the first via 161 may include a first sidewall 161s1 in contact with the buffer insulating layer 130, a second sidewall 161s2 in contact with the resistance pattern 140, and/or a third sidewall 161s3 in contact with the second interlayer insulating layer 150. For example, the first sidewall 161s1 of the first via 161, the second sidewall 161s2 of the first via 161, and the third sidewall 161s3 of the first via 161 may have a continuous inclination profile.

A second via 162 may be disposed inside the second via trench 162T. The second via 162 may extend through the second interlayer insulating layer 150, the buffer insulating layer 130, and/or the etch-stop layer 120 in the vertical direction DR3 so as to be connected to the lower wiring pattern 110. For example, a lower surface of the second via 162 may contact the lower wiring pattern 110. For example, the second via 162 may be spaced apart from the first via 161 in the first horizontal direction DR1. For example, the second via 162 may be spaced apart from the resistance pattern 140 in the first horizontal direction DR1.

For example, a vertical level of the lower surface of the second via 162 may be lower than a vertical level of the lower surface of the first via 161. For example, a vertical level of the upper surface of the second via 162 may be lower than a vertical level of the upper surface of the second interlayer insulating layer 150. For example, the upper surface of the second via 162 may be coplanar with the upper surface of the first via 161. However, example embodiments are not limited thereto. For example, both opposing sidewalls in the first horizontal direction DR1 of the second via 162 may contact each, or one or more, of the etch-stop layer 120, the buffer insulating layer 130, and/or the second interlayer insulating layer 150. For example, the etch-stop layer 120 may surround a portion of the sidewall of the second via 162.

A first upper wiring trench 171T may be formed on an upper surface of the first via trench 161T. The first upper wiring trench 171T may be formed in the second interlayer insulating layer 150. For example, the first upper wiring trench 171T may extend in the second horizontal direction DR2. For example, a width of a bottom surface of the first upper wiring trench 171T in the first horizontal direction DR1 may be greater than a width of the upper surface of the first via trench 161T in the first horizontal direction DR1.

A second upper wiring trench 172T may be formed on the upper surface of the second via trench 162T. The second upper wiring trench 172T may be formed in the second interlayer insulating layer 150. The second upper wiring trench 172T may be spaced apart from the first upper wiring trench 171T in the first horizontal direction DR1. For example, the second upper wiring trench 172T may extend in the second horizontal direction DR2. For example, a width of a bottom surface of the second upper wiring trench 172T in the first horizontal direction DR1 may be greater than a width of an upper surface of the second via trench 162T in the first horizontal direction DR1.

The first upper wiring pattern 171 may be disposed inside the first upper wiring trench 171T. For example, the first upper wiring pattern 171 may be disposed inside the second interlayer insulating layer 150. For example, the first upper wiring pattern 171 may extend in the second horizontal direction DR2. However, example embodiments are not limited thereto. A lower surface of the first upper wiring pattern 171 may be in contact with an upper surface of the first via 161. For example, a width of a lower surface of the first upper wiring pattern 171 in the first horizontal direction DR1 may be greater than a width of an upper surface of the first via 161 in the first horizontal direction DR1. For example, at least a portion of the lower surface of the first upper wiring pattern 171 may be in contact with the second interlayer insulating layer 150. For example, the upper surface of the first upper wiring pattern 171 may be coplanar with the upper surface of the second interlayer insulating layer 150.

The second upper wiring pattern 172 may be disposed in the second upper wiring trench 172T. For example, the second upper wiring pattern 172 may be disposed inside the second interlayer insulating layer 150. The second upper wiring pattern 172 may be spaced apart from the first upper wiring pattern 171 in the first horizontal direction DR1. For example, the second upper wiring pattern 172 may extend in the second horizontal direction DR2. However, example embodiments are not limited thereto. A lower surface of the second upper wiring pattern 172 may be in contact with an upper surface of the second via 162. For example, a width of a lower surface of the second upper wiring pattern 172 in the first horizontal direction DR1 may be greater than a width of an upper surface of the second via 162 in the first horizontal direction DR1. For example, at least a portion of the lower surface of the second upper wiring pattern 172 may contact the second interlayer insulating layer 150. For example, the upper surface of the second upper wiring pattern 172 may be coplanar with the upper surface of the second interlayer insulating layer 150.

For example, the first upper wiring pattern 171 and the first via 161 may be formed integrally with each other. In this regard, being formed integrally with each other means that the first upper wiring pattern 171 and the first via 161 include the same material and the first upper wiring pattern 171 and the first via 161 are formed in the same fabricating process. For example, the second upper wiring pattern 172 and the second via 162 may be formed integrally with each other. For example, each, or one or more, of the first via 161, the second via 162, the first upper wiring pattern 171, and/or the second upper wiring pattern 172 may include a second wiring barrier layer 181 and/or a second wiring filling layer 182.

The second wiring barrier layer 181 may be disposed along the sidewall and the bottom surface of each, or one or more, of the first and/or second via trenches 161T and/or 162T. For example, the second wiring barrier layer 181 may be disposed along the sidewall and/or the bottom surface of each, or one or more, of the first and/or second upper wiring trenches 171T and/or 172T. However, the second wiring barrier layer 181 may not be disposed on a portion of each, or one or more, of the bottom surfaces of the first and/or second upper wiring trenches 171T and/or 172T respectively overlapping the first and second via trenches 161T and 162T in the vertical direction DR3. For example, the second wiring barrier layer 181 may be conformally formed.

For example, the uppermost surface of the second wiring barrier layer 181 may not be covered with the upper surface of the second interlayer insulating layer 150 so as to be exposed. For example, the second wiring barrier layer 181 may include at least one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), and/or a combination thereof. However, example embodiments are not limited thereto.

The second wiring filling layer 182 may be disposed on the second wiring barrier layer 181 and inside each, or one or more, of the first and/or second via trenches 161T and/or 162T and/or the first and/or second upper wiring trenches 171T and/or 172T. The second wiring filling layer 182 may fill the inside of each, or one or more, of the first and second via trenches 161T and/or 162T and/or the first and/or second upper wiring trenches 171T and/or 172T while being disposed on the second wiring barrier layer 181.

For example, the uppermost surface of the second wiring filling layer 182 may not be covered with the upper surface of the second interlayer insulating layer 150 so as to be exposed. For example, the second wiring filling layer 182 may include at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), and/or rhodium (Rh). However, example embodiments are not limited thereto.

For example, when a separate etch-stop layer is disposed on the upper surface of the resistance pattern 140, a problem may occur in which the resistance pattern 140 is not opened in the process of forming the first via trench 161T. In the semiconductor device according to some example embodiments of the inventive concepts, the separate etch-stop layer may not be disposed on the upper surface of the resistance pattern 140, and the upper surface of the resistance pattern 140 may be in contact with the second interlayer insulating layer 150. For example, the first via 161 may extend through the resistance pattern 140 in the vertical direction DR3. Accordingly, the semiconductor device according to some example embodiments may improve the reliability of the connection between the first via 161 and the resistance pattern 140.

Hereinafter, a method for fabricating a semiconductor device according to some example embodiments of the inventive concepts will be described with reference to FIGS. 2 to 8.

FIGS. 4 to 8 are diagrams illustrating intermediate structures corresponding to intermediate steps of a method for fabricating a semiconductor device according to some example embodiments of the inventive concepts.

Referring to FIG. 4, the first interlayer insulating layer 105 may be formed on the upper surface of the substrate 100. Subsequently, the lower wiring trench 110T may be formed in the first interlayer insulating layer 105. The lower wiring trench 110T may be formed to be recessed from the upper surface of the first interlayer insulating layer 105 toward the inside of the first interlayer insulating layer 105.

Subsequently, the lower wiring pattern 110 including the first wiring barrier layer 111 and/or the first wiring filling layer 112 may be formed in the lower wiring trench 110T. The first wiring barrier layer 111 may be formed along the sidewall and/or the bottom surface of the lower wiring trench 110T. For example, the first wiring barrier layer 111 may be conformally formed. The first wiring filling layer 112 may fill the inside of the lower wiring trench 110T while being disposed on the first wiring barrier layer 111.

Referring to FIG. 5, the etch-stop layer 120, the buffer insulating layer 130, and/or a resistance material layer 140M may be sequentially formed on the upper surface of each, or one or more, of the first interlayer insulating layer 105 and/or the lower wiring pattern 110. For example, the lower surface of the etch-stop layer 120 may contact the upper surface of each, or one or more, of the first interlayer insulating layer 105 and/or the lower wiring pattern 110. The lower surface of the buffer insulating layer 130 may be in contact with the upper surface of the etch-stop layer 120. The lower surface of the resistance material layer 140M may be in contact with the upper surface of the buffer insulating layer 130. For example, each, or one or more, of the etch-stop layer 120, the buffer insulating layer 130, and/or the resistance material layer 140M may be conformally formed. For example, the resistance material layer 140M may include the same material as that of the resistance pattern 140 as illustrated in FIG. 2.

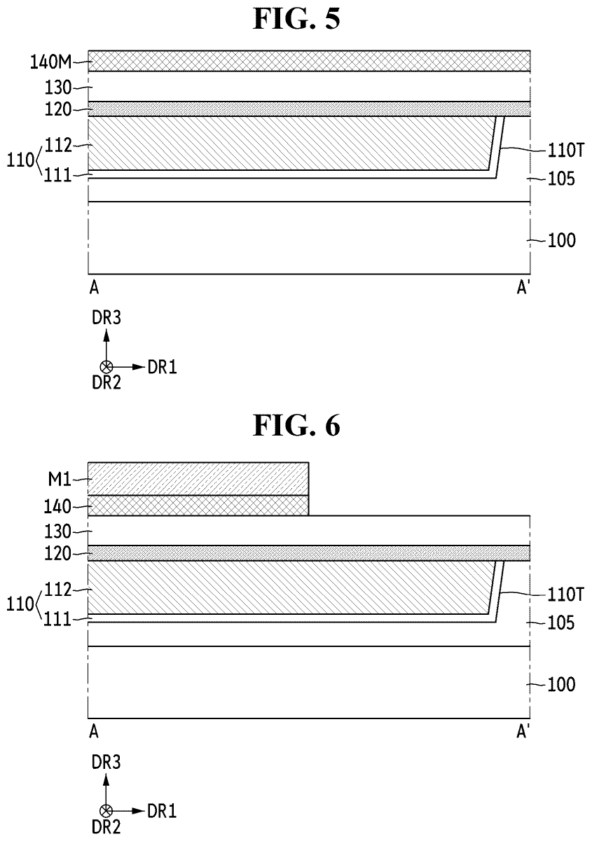

Referring to FIG. 6, a mask pattern M1 may be formed on an upper surface of the resistance material layer (140M of FIG. 5). Subsequently, a portion of the resistance material layer 140M of FIG. 5 may be etched using the mask pattern M1 as a mask. After the etching process has been completed, the remaining resistance material layer 140M of FIG. 5 may be defined as the resistance pattern 140. For example, the upper surface of the buffer insulating layer 130 may not be covered with the sidewall of the resistance pattern 140 so as to be exposed.

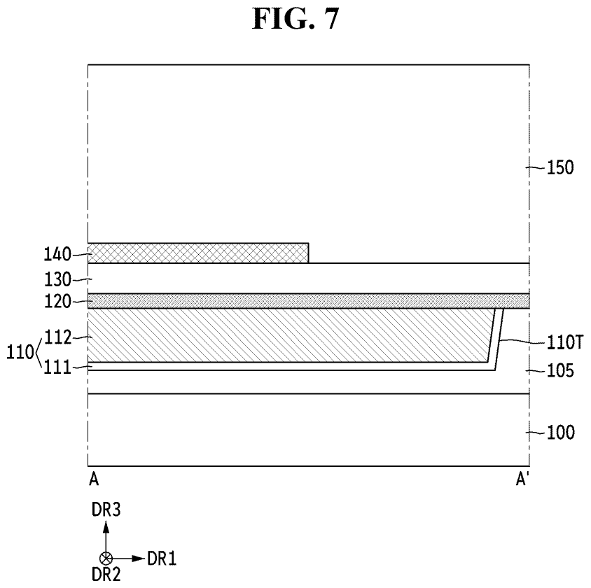

Referring to FIG. 7, the mask pattern M1 of FIG. 6 may be removed. Next, the second interlayer insulating layer 150 may be formed on the upper surface of the buffer insulating layer 130 so as to cover the upper surface and/or the sidewall of the resistance pattern 140. For example, the second interlayer insulating layer 150 may be in contact with each, or one or more, of the upper surface and/or the sidewall of the resistance pattern 140. For example, the second interlayer insulating layer 150 may be in contact with the upper surface of the buffer insulating layer 130 while being disposed on the sidewall of the resistance pattern 140.

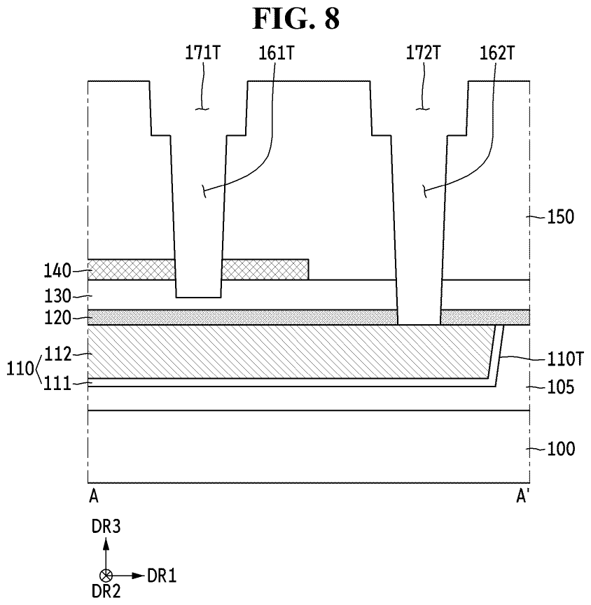

Referring to FIG. 8, the first via trench 161T extending through the second interlayer insulating layer 150 and/or the resistance pattern 140 into the buffer insulating layer 130 in the vertical direction DR3 may be formed. The second via trench 162T may be formed to extend through the second interlayer insulating layer 150, the buffer insulating layer 130, and/or the etch-stop layer 120 in the vertical direction DR3 so as to expose the upper surface of the lower wiring pattern 110. For example, the first upper wiring trench 171T may be formed on the upper surface of the first via trench 161T, and the second upper wiring trench 172T may be formed on the upper surface of the second via trench 162T.

Referring to FIGS. 2 and 3, the second wiring barrier layer 181 may be formed along an exposed surface of each, or one or more, of the first and second via trenches 161T and/or 162T and/or the first and/or second upper wiring trenches 171T and/or 172T. For example, the second wiring barrier layer 181 may be conformally formed. Next, the second wiring filling layer 182 may be formed on the second wiring barrier layer 181 so as to fill the inside of each, or one or more, of the first and/or second via trenches 161T and/or 162T and/or the first and/or second upper wiring trenches 171T and/or 172T.

For example, the first via 161 may be formed inside the first via trench 161T, and the second via 162 may be formed inside the second via trench 162T. For example, the first upper wiring pattern 171 may be formed inside the first upper wiring trench 171T, and the second upper wiring pattern 172 may be formed inside the second upper wiring trench 172T. For example, the first via 161, the second via 162, the first upper wiring pattern 171, and/or the second upper wiring pattern 172 may be formed in the same fabricating process. Through this fabricating process, the semiconductor device as illustrated in FIGS. 2 and 3 may be fabricated.

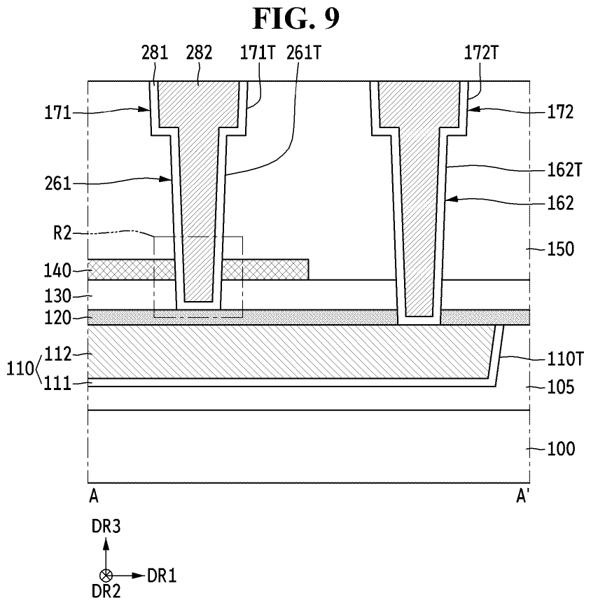

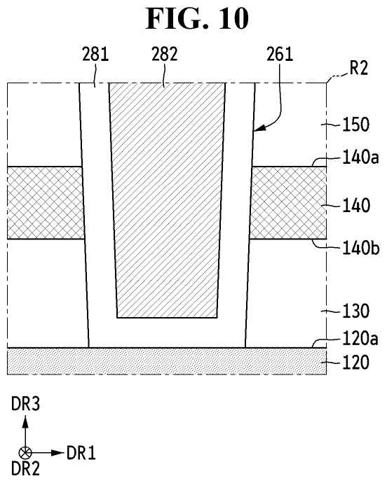

Hereinafter, a semiconductor device according to some example embodiments of the inventive concepts will be described with reference to FIGS. 9 and 10. Differences thereof from the semiconductor device as illustrated in FIGS. 1 to 3 will be mainly described.

FIG. 9 is a cross-sectional view illustrating a semiconductor device according to some example embodiments of the inventive concepts. FIG. 10 is an enlarged view of a region R2 of FIG. 9.

Referring to FIGS. 9 and 10, in the semiconductor device according to some example embodiments of the inventive concepts, the lower surface of the first via 261 may contact the upper surface 120a of the etch-stop layer 120.

For example, the first via trench 261T may extend through the second interlayer insulating layer 150, the resistance pattern 140, and/or the buffer insulating layer 130 in the vertical direction DR3 so as to extend to the upper surface 120a of the etch-stop layer 120. The first via 261 may be disposed inside the first via trench 261T. The first via 261 may extend through the second interlayer insulating layer 150, the resistance pattern 140 and/or the buffer insulating layer 130 in the vertical direction DR3 so as to extend to the upper surface 120a of the etch-stop layer 120. The lower surface of the first via 261 may be in contact with the upper surface 120a of the etch-stop layer 120.

The second wiring barrier layer 281 may be disposed along the sidewall and/or the bottom surface of each, or one or more, of the first and/or second via trenches 261T and/or 162T. For example, the second wiring barrier layer 281 may be disposed along the sidewall and/or the bottom surface of each, or one or more, of the first and/or second upper wiring trenches 171T and/or 172T. For example, the second wiring barrier layer 281 may be conformally formed. The second wiring filling layer 282 may be disposed on the second wiring barrier layer 281 and/or inside each of the first and/or second via trenches 261T and/or 162T and/or the first and/or second upper wiring trenches 171T and/or 172T. The second wiring filling layer 282 may fill the inside of each, or one or more, of the first and/or second via trenches 261T and/or 162T and/or the first and/or second upper wiring trenches 171T and/or 172T while being disposed on the second wiring barrier layer 281.

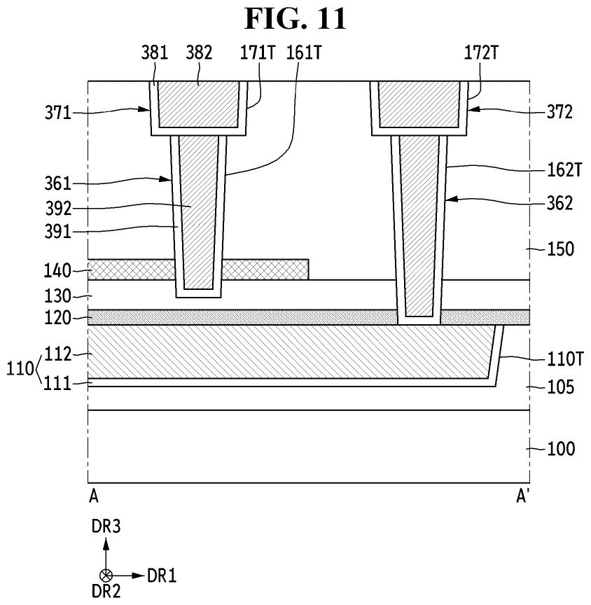

Hereinafter, a semiconductor device according to some example embodiments of the inventive concepts will be described with reference to FIG. 11. Differences thereof from the semiconductor device as illustrated in FIGS. 1 to 3 will be mainly described.

FIG. 11 is a cross-sectional view illustrating a semiconductor device according to some example embodiments of the inventive concepts.

Referring to FIG. 11, in the semiconductor device according to some example embodiments of the inventive concepts, each, or one or more, of the first via 361 and/or the second via 362 may include a via barrier layer 391 and a via filling layer 392.

For example, the via barrier layer 391 may be disposed along the sidewall and/or the bottom surface of each, or one or more, of the first and/or second via trenches 161T and/or 162T. For example, the via barrier layer 391 may be conformally formed. For example, the via barrier layer 391 may include at least one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), and/or a combination thereof. However, example embodiments are not limited thereto.

For example, the via filling layer 392 may be disposed on the via barrier layer 391 and/or inside each, or one or more, of the first and/or second via trenches 161T and/or 162T. The via filling layer 392 may fill the inside of each, or one or more, of the first and/or second via trenches 161T and/or 162T while being disposed on the via barrier layer 391. For example, the via filling layer 392 may include at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), and/or rhodium (Rh). However, example embodiments are not limited thereto.

For example, each, or one or more, of the first upper wiring pattern 371 and/or the second upper wiring pattern 372 may include a second wiring barrier layer 381 and/or a second wiring filling layer 382. For example, the second wiring barrier layer 381 may be disposed along the sidewall and/or the bottom surface of each, or one or more, of the first and/or second upper wiring trenches 171T and/or 172T. For example, the second wiring barrier layer 381 may contact the upper surface of each of the via barrier layer 391 and the via filling layer 392. For example, the second wiring barrier layer 381 may be conformally formed. For example, the second wiring filling layer 382 may be disposed on the second wiring barrier layer 381 and/or inside each, or one or more, of the first and second upper wiring trenches 171T and/or 172T. The second wiring filling layer 382 may fill the inside of each, or one or more, of the first and/or second upper wiring trenches 171T and/or 172T while being disposed on the second wiring barrier layer 381. For example, the second wiring filling layer 382 may be spaced apart from the via filling layer 392 in the vertical direction DR3.

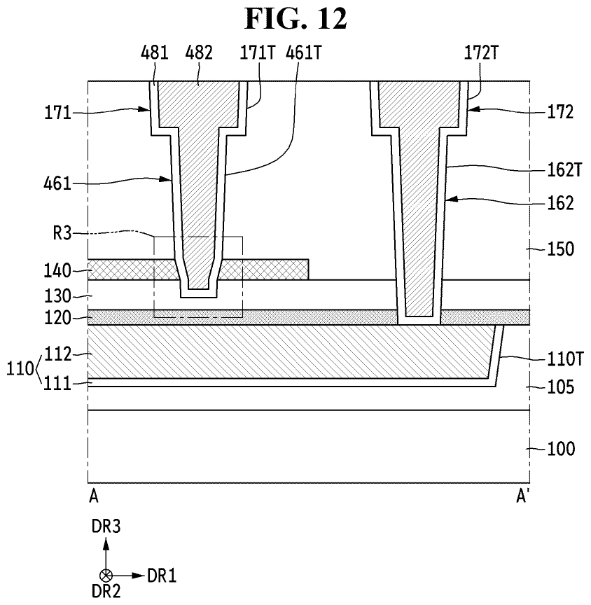

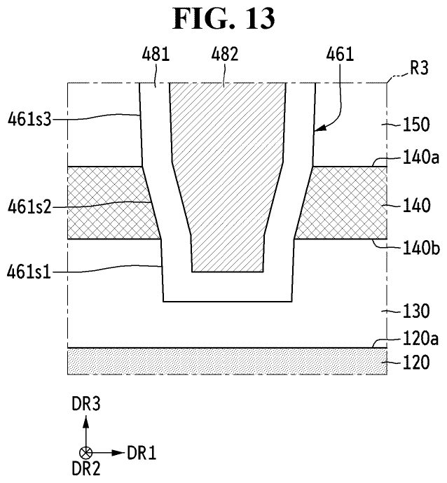

Hereinafter, a semiconductor device according to some example embodiments of the inventive concepts will be described with reference to FIGS. 12 and 13. Differences thereof from the semiconductor device as illustrated in FIGS. 1 to 3 will be mainly described.

FIG. 12 is a cross-sectional view illustrating a semiconductor device according to some example embodiments of the inventive concepts. FIG. 13 is an enlarged view of a region R3 of FIG. 12.

Referring to FIGS. 12 and 13, in the semiconductor device according to some example embodiments of the inventive concepts, a sidewall of a first via 461 may include a first sidewall 461s1 in contact with the buffer insulating layer 130, a second sidewall 461s2 in contact with the resistance pattern 140, and/or a third sidewall 461s3 in contact with the second interlayer insulating layer 150.

For example, the sidewall of the first via trench 461T may have different inclination profiles respectively inside the buffer insulating layer 130, the resistance pattern 140, and/or the second interlayer insulating layer 150. The first via 461 may be disposed inside the first via trench 461T. For example, the inclination profile of the first sidewall 461s1 of the first via 461 may be different from the inclination profile of the second sidewall 461s2 of the first via 461. The inclination profile of the first sidewall 461s1 of the first via 461 and the inclination profile of the second sidewall 461s2 of the first via 461 may meet each other at the lower surface 140b of the resistance pattern 140. For example, the inclination profile of the third sidewall 461s3 of the first via 461 may be different from the inclination profile of the second sidewall 461s2 of the first via 461. The inclination profile of the third sidewall 461s3 of the first via 461 and the inclination profile of the second sidewall 461s2 of the first via 461 may meet each other at the upper surface 140a of the resistance pattern 140.

A second wiring barrier layer 481 may be disposed along the sidewall and/or the bottom surface of each, or one or more, of the first and/or second via trenches 461T and/or 162T. For example, the second wiring barrier layer 481 may be disposed along the sidewall and/or the bottom surface of each, or one or more, of the first and/or second upper wiring trenches 171T and/or 172T. For example, the second wiring barrier layer 481 may be conformally formed. The second wiring filling layer 482 may be disposed on the second wiring barrier layer 481 and/or inside each, or one or more, of the first and/or second via trenches 461T and/or 162T and/or the first and/or second upper wiring trenches 171T and/or 172T. A second wiring filling layer 482 may fill the inside of each, or one or more, of the first and/or second via trenches 461T and/or 162T and/or the first and/or second upper wiring trenches 171T and/or 172T while being disposed on the second wiring barrier layer 481.

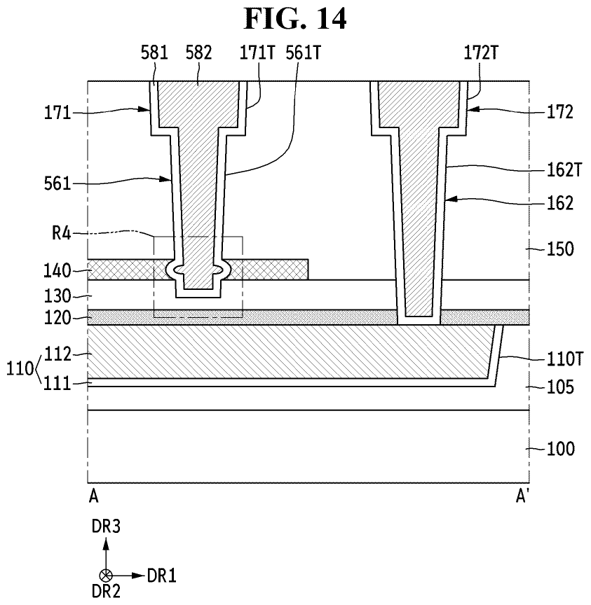

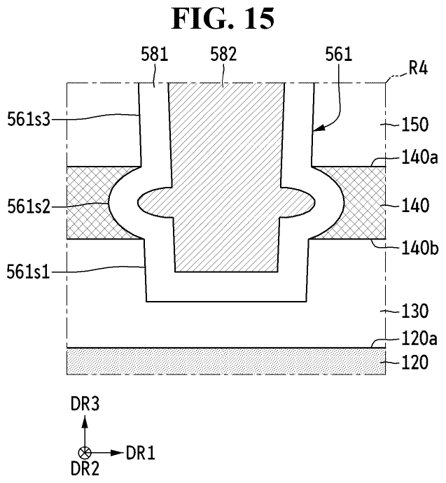

Hereinafter, a semiconductor device according to some example embodiments of the inventive concepts will be described with reference to FIGS. 14 and 15. Differences thereof from the semiconductor device as illustrated in FIGS. 1 to 3 will be mainly described.

FIG. 14 is a cross-sectional view illustrating a semiconductor device according to some example embodiments of the inventive concepts. FIG. 15 is an enlarged view of a region R4 of FIG. 14.

Referring to FIGS. 14 and 15, in the semiconductor device according to some example embodiments of the inventive concepts, a sidewall of a first via 561 in contact with the resistance pattern 140 may be formed to be convex toward the resistance pattern 140.

For example, a sidewall of a first via trench 561T may have different inclination profiles respectively inside the buffer insulating layer 130, the resistance pattern 140, and/or the second interlayer insulating layer 150. The first via 561 may be disposed inside the first via trench 561T. For example, an inclination profile of a first sidewall 561s1 of the first via 561 may be different from an inclination profile of a second sidewall 561s2 of the first via 561. For example, the sidewall of the first via 561 may include the first sidewall 561s1 in contact with the buffer insulating layer 130, the second sidewall 561s2 in contact with the resistance pattern 140, and/or a third sidewall 561s3 in contact with the second interlayer insulating layer 150. The inclination profile of the first sidewall 561s1 of the first via 561 and the inclination profile of the second sidewall 561s2 of the first via 561 may meet each other at the lower surface 140b of the resistance pattern 140. For example, an inclination profile of the third sidewall 561s3 of the first via 561 may be different from the inclination profile of the second sidewall 561s2 of the first via 561. The inclination profile of the third sidewall 561s3 of the first via 561 and the inclination profile of the second sidewall 561s2 of the first via 561 may meet each other at the upper surface 140a of the resistance pattern 140. For example, the second sidewall 561s2 of the first via 561 may protrude toward the resistance pattern 140 beyond each, or one or more, of the first sidewall 561s1 of the first via 561 and/or the third sidewall 561s3 of the first via 561.

A second wiring barrier layer 581 may be disposed along the sidewall and the bottom surface of each, or one or more, of first and/or second via trenches 561T and/or 162T. For example, the second wiring barrier layer 581 may be disposed along the sidewall and/or the bottom surface of each, or one or more, of the first and/or second upper wiring trenches 171T and/or 172T. For example, the second wiring barrier layer 581 may be conformally formed. The second wiring filling layer 582 may be disposed on the second wiring barrier layer 581 and/or inside each, or one or more, of the first and/or second via trenches 561T and/or 162T and/or the first and/or second upper wiring trenches 171T and/or 172T. A second wiring filling layer 582 may fill the inside of each, or one or more, of the first and/or second via trenches 561T and/or 162T and/or the first and/or second upper wiring trenches 171T and/or 172T while being disposed on the second wiring barrier layer 581.

Although some example embodiments according to the inventive concepts have been described with reference to the accompanying drawings, the inventive concepts are not limited to the above example embodiments, but may be fabricated in various different forms, and it will be understood that those skilled in the art to which the inventive concepts pertain may be implemented in other specific forms without changing the technical idea or essential features of the inventive concepts.

Therefore, it should be understood that the embodiments described above are exemplary in all aspects and are not limited thereto.

Although some embodiments of the inventive concepts have been described with reference to the accompanying drawings, the inventive concepts are not limited to the above example embodiments, but may be implemented in various different forms. A person skilled in the art may appreciate that the inventive concepts may be practiced in other concrete forms without changing the technical spirit or essential characteristics of the inventive concepts. Therefore, it should be appreciated that the example embodiments as described above are not restrictive but illustrative in all respects.

What is claimed is:

1. A semiconductor device comprising:
a first interlayer insulating layer;
a lower wiring pattern inside the first interlayer insulating layer;
a buffer insulating layer on an upper surface of each of the lower wiring pattern and the first interlayer insulating layer;
a resistance pattern in contact with an upper surface of the buffer insulating layer;
a second interlayer insulating layer on the upper surface of the buffer insulating layer, the second interlayer insulating layer in contact with each of an upper surface and a sidewall of the resistance pattern;
a first via extending, in a vertical direction, through the second interlayer insulating layer and the resistance pattern and into the buffer insulating layer, a vertical level of a lower surface of the first via being lower than a vertical level of a lower surface of the resistance pattern; and
a second via spaced apart from the first via in a horizontal direction, the second via extending, in the vertical direction, through the second interlayer insulating layer and the buffer insulating layer, the second via being connected to the lower wiring pattern.

2. The semiconductor device of claim 1, further comprising:
an etch-stop layer between the upper surface of the lower wiring pattern and a lower surface of the buffer insulating layer, the etch-stop layer overlapping the first via in the vertical direction, and the etch-stop layer surrounding a portion of a sidewall of the second via.

3. The semiconductor device of claim 2, wherein the lower surface of the first via is spaced apart from an upper surface of the etch-stop layer in the vertical direction.

4. The semiconductor device of claim 2, wherein the lower surface of the first via is in contact with an upper surface of the etch-stop layer.

5. The semiconductor device of claim 1, wherein the second via is spaced apart from the resistance pattern in the horizontal direction.

6. The semiconductor device of claim 1, wherein at least a portion of the upper surface of the buffer insulating layer is in contact with the second interlayer insulating layer.

7. The semiconductor device of claim 1, wherein a vertical level of a lower surface of the second via is lower than the vertical level of the lower surface of the first via.

8. The semiconductor device of claim 1, further comprising:
a first upper wiring pattern in the second interlayer insulating layer, the first upper wiring pattern being in contact with an upper surface of the first via, and a width in the horizontal direction of a lower surface the first upper wiring pattern being greater than a width in the horizontal direction of the upper surface of the first via; and
a second upper wiring pattern in the second interlayer insulating layer, the second upper wiring pattern being in contact with an upper surface of the second via, a width in the horizontal direction of a lower surface of the second upper wiring pattern being greater than a width in the horizontal direction of the upper surface of the second via, and the second upper wiring pattern being spaced apart from the first upper wiring pattern in the horizontal direction.

9. The semiconductor device of claim 8, wherein
the first via and the first upper wiring pattern are formed integrally with each other, and
the second via and the second upper wiring pattern are formed integrally with each other.

10. The semiconductor device of claim 1, wherein
a sidewall of the first via includes a first sidewall in contact with the buffer insulating layer, a second sidewall in contact with the resistance pattern, and a third sidewall in contact with the second interlayer insulating layer, and
an inclination profile of the first sidewall of the first via is different from an inclination profile of the second sidewall of the first via.

11. The semiconductor device of claim 10, wherein an inclination profile of the third sidewall of the first via is different from the inclination profile of the second sidewall of the first via.

12. The semiconductor device of claim 10, wherein the second sidewall of the first via is convex toward the resistance pattern.

13. A semiconductor device comprising:
a first interlayer insulating layer;
a lower wiring pattern inside the first interlayer insulating layer;
an etch-stop layer on an upper surface of each of the lower wiring pattern and the first interlayer insulating layer;
a buffer insulating layer in contact with an upper surface of the etch-stop layer;
a resistance pattern in contact with an upper surface of the buffer insulating layer;
a second interlayer insulating layer on the upper surface of the buffer insulating layer, the second interlayer insulating layer in contact with each of an upper surface and a sidewall of the resistance pattern;
a first via extending, in a vertical direction, through the second interlayer insulating layer and the resistance pattern and into the buffer insulating layer, a vertical level of a lower surface of the first via being lower than a vertical level of a lower surface of the resistance pattern, and the first via overlapping the etch-stop layer in the vertical direction; and
a first upper wiring pattern in the second interlayer insulating layer, the first upper wiring pattern being in contact with an upper surface of the first via, and a width in a horizontal direction of a lower surface of the first upper wiring pattern being greater than a width in the horizontal direction of the upper surface of the first via.

14. The semiconductor device of claim 13, further comprising:
a second via spaced apart from the resistance pattern in the horizontal direction, the second via extending through the second interlayer insulating layer, the buffer insulating layer and the etch-stop layer in the vertical direction, and the second via being connected to the lower wiring pattern.

15. The semiconductor device of claim 13, wherein the lower surface of the first via is spaced apart from the upper surface of the etch-stop layer in the vertical direction.

16. The semiconductor device of claim 13, wherein the lower surface of the first via is in contact with the upper surface of the etch-stop layer.

17. The semiconductor device of claim 13, wherein the first via and the first upper wiring pattern are formed integrally with each other.

18. The device of claim 13, wherein
a sidewall of the first via includes a first sidewall in contact with the buffer insulating layer, a second sidewall in contact with the resistance pattern, and a third sidewall in contact with the second interlayer insulating layer, and
each of an inclination profile of the first sidewall of the first via and an inclination profile of the third sidewall of the first via is different from an inclination profile of the second sidewall of the first via.

19. The semiconductor device of claim 18, wherein the second sidewall of the first via is convex toward the resistance pattern.

20. A semiconductor device comprising:
a first interlayer insulating layer;
a lower wiring pattern inside the first interlayer insulating layer;
an etch-stop layer on an upper surface of each of the lower wiring pattern and the first interlayer insulating layer;
a buffer insulating layer in contact with an upper surface of the etch-stop layer;
a resistance pattern in contact with an upper surface of the buffer insulating layer;
a second interlayer insulating layer on the upper surface of the buffer insulating layer, the second interlayer insulating layer in contact with a portion of the upper surface of the buffer insulating layer and each of an upper surface and a sidewall of the resistance pattern;
a first via extending, in a vertical direction, through the second interlayer insulating layer and the resistance pattern and into the buffer insulating layer, a vertical level of a lower surface of the first via being lower than a vertical level of a lower surface of the resistance pattern, the first via overlapping the etch-stop layer in the vertical direction, and the lower surface of the first via being spaced apart from the upper surface of the etch-stop layer in the vertical direction;
a second via spaced apart from the resistance pattern in a horizontal direction, the second via extending through the second interlayer insulating layer, the buffer insulating layer, and the etch-stop layer in the vertical direction, the second via being connected to the lower wiring pattern, and a vertical level of a lower surface of the second via being lower than the vertical level of the lower surface of the first via;
a first upper wiring pattern in the second interlayer insulating layer, the first upper wiring pattern being in contact with an upper surface of the first via, a width in the horizontal direction of a lower surface of the first upper wiring pattern being greater than a width in the horizontal direction of the upper surface of the first via, and the first via and the first upper wiring pattern being formed integrally with each other; and
a second upper wiring pattern in the second interlayer insulating layer, the second upper wiring pattern being in contact with an upper surface of the second via, a width in the horizontal direction of a lower surface of the second upper wiring pattern being greater than a width in the horizontal direction of the upper surface of the second via, the second upper wiring pattern being spaced apart from the first upper wiring pattern in the horizontal direction, and the second via and the second upper wiring pattern being formed integrally with each other.
